(19) United States
(12) Patent Application Publication
(10) Pub. No.: US 2010/0038663 A1
(43) Pub. Date: Feb. 18, 2010

(54) LED LIGHT RECYCLING FOR LUMINANCE ENHANCEMENT AND ANGULAR NARROWING

(75) Inventors: Pablo BENITEZ, Madrid (ES); Juan Carlos MINANO, Madrid (ES); Julio Cesar CHAVES, Madrid (ES); William A. PARKYN, JR., Lomita, CA (US); Waqidi FALICOFF, Stevenson Ranch, CA (US)

Correspondence Address: SINSHEIMER JUHNKE LEBENS & MCIVOR, LLP, 1010 PEACH STREET, P.O. BOX 31, SAN LUIS OBISPO, CA, 93406, US

(73) Assignee: LIGHT PRESCRIPTIONS INNOVATORS, LLC, Altadena, CA (US)

(21) Appl. No.: 12/368,991

(22) Filed: Feb. 10, 2009

Related U.S. Application Data
(63) Continuation of application No. PCT/US07/75779, filed on Aug. 13, 2007.
(60) Provisional application No. 60/822,075, filed on Aug. 10, 2006.

(51) Int. Cl. H01L 33/00

(52) U.S. Cl. 257/98; 257/E33.067

(57) ABSTRACT

Some embodiments provide a luminance-enhanced light source. These embodiments include a thin-film LED mounted on a substrate and with a defined upper surface approximately hemispherically emitting light, with the upper surface being diffusely transmissive, a lower first layer of identically defined linear prismatic film separated from the upper surface by a non-evanescent air gap so as to cover the upper surface, a upper second layer of linear prismatic film, identical to but oriented orthogonally to the first layer, and a circumferential vertical reflective wall bordering on both of the first and second layers and extending in height from the substrate to the top of the second layer.

### PRIORITY CLAIM

This application is a Continuation of Internation Patent Application No. PCT/US07/75779 filed Aug. 13, 2007, entitled LED LIGHT RECYCLING FOR LUMINANCE ENHANCEMENT AND ANGULAR NARROWING, which claims the benefit of U.S. Provisional Application No. 60/822,075, filed Aug. 10, 2006, entitled LED LIGHT-RECYCLING FOR LUMINANCE-ENHANCEMENT AND ANGULAR-NARROWING, boht of which are incorporated herein by reference in their entireties.

### FIELD OF THE INVENTION

The present invention relates generally to luminaries, and more particularly to luminaries in cooperation with light emitting diodes.

### BACKGROUND

The use of light emitting diodes (LED) has increased dramatically over the last few decades. Numerous applications for LEDs have been identified and continue to be identified.

LEDs alone typically emitted relatively low light emissions as compared with many other types of light sources. Further, many LEDs often emit light in substantially a hemispheric emission pattern. As a result, the use of LEDs for some implementations has been limited.

### SUMMARY OF THE EMBODIMENTS

The present embodiments advantageously addresses the needs above as well as other needs through the provision of the methods and apparatuses for use in enhancing luminance of one or more LEDs. Some embodiments provide a luminance-enhanced light source. These embodiments include a thin-film LED mounted on a substrate and with a defined upper surface approximately hemispherically emitting light, said upper surface being diffusely transmissive, a lower first layer of identically defined linear prismatic film separated from said upper surface by a non-evanescent air gap so as to cover said upper surface, a upper second layer of linear prismatic film, identical to but oriented orthogonally to said first layer, and a circumferential vertical reflective wall bordering on both of said first and second layers and extending in height from said substrate to a top of said second layer.

Other embodiments provide luminance-enhanced light sources. These sources include a thin-film LED with a defined upper surface hemispherically emitting light, a reflective upper layer in optical contact with said LED, said upper layer having an array of holes providing passage of luminance-enhanced light out of said LED, and an array of collimating means aligned in correspondence to said holes in order to receive said luminance-enhanced light and to expand a cross sectional exit area of the luminance-enhanced light to a majority of an area of said upper surface of said LED.

Some embodiments provide luminance-enhanced light sources that include a line of a plurality of spaced LEDs and two linearly swept elliptical reflectors disposed symmetrically on opposing sides of the line of LEDs and defining an aperture above said line of LEDs, said reflectors with elliptical profiles each having a first focus on an opposite edge of said line of LEDs and a second focus on an opposite edge of said aperture.

Further embodiments provide luminance-enhanced light sources that include an LED and a rotationally symmetric elliptical reflector, said reflector with elliptical profile having a circular focus defined at an opposite edge of the circular profile from the elliptical reflector where the circular focus has a radius substantially encompassing said LED.

A better understanding of the features and advantages of the present invention will be obtained by reference to the following detailed description of the invention and accompanying drawings which set forth an illustrative embodiment in which the principles of the invention are utilized.

### BRIEF DESCRIPTION OF THE DRAWINGS

The above and other aspects, features and advantages of the present invention will be more apparent from the following more particular description thereof, presented in conjunction with the following drawings wherein:

FIG. 1 shows a cross-section of a thin-film LED.

FIG. 2 shows same with a brightness enhancing film (BEF), positioned above it.

FIG. 3 is a perspective view of same with a pair of crossed BEFs.

FIG. 4A is a perspective top view of an array of compound parabolic concentrators (CPCs).

FIG. 4B is a perspective bottom view of same.

FIG. 5 shows a cross-section of a thin-film LED with an overlying array of 300 CPCs.

FIG. 6 shows a cross-section of a thin-film LED with an overlying array of 200 CPCs.

FIG. 7 shows luminance enhancement of a line of LEDs by the use of a cylindrical elliptical cavity.

FIG. 8 shows luminance enhancement of an LED by use of a rotational symmetric elliptical cavity.

FIG. 9 shows cross-section of luminance enhancement of LED by an air-filled elliptical cavity with a condenser lens at its exit aperture.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION OF EMBODIMENTS

Light emitting diode (LED) chips typically contain a thin volume of emitting semiconductor of relatively high refractive index (e.g., 2.5 to 3.5). This high index can cause a correspondingly high degree of light-trapping, which in many instances is deleterious for light extraction from the chip. Extraction is hindered by of internal absorption, which converts most of the trapped light into heat as path-length increasing due to repeated internal reflections. This repetition can be curtailed by asymmetric chip-shaping or by surface roughening. Whatever the extraction efficiency, however, the emitting surfaces of LEDs radiate typically into a nearly full hemisphere, which is to say, with low angular selectivity.

Some luminaires are fashioned to transform such wide-angle radiation into intensity patterns that are, for example, usefully restricted to a beam. In the case of LEDs, such luminaires can be quite small (e.g., under an inch), but still typically much larger than the LED chips themselves. Additionally, these luminaires multiply emission area, but generally do not increase emission luminance since they typically are inherently passive devices. That is to say, the lit appearance of the luminaire will generally look no brighter than the source itself. Some present embodiments, however, provide methods of amplifying the chip's luminance itself, something heretofore generally seen only in lasers.

Higher luminance is particularly valuable, for example, in image-projection applications, where the etendue of the spatial light modulator is a limiting factor on the flux that can be transferred through the system. Therefore, increasing that flux typically cannot be done by increasing the number of LEDs, but by increasing their luminance. Some embodiments increase luminance, for example by increasing the current. Additionally, the some present embodiments provide a higher luminance to the LED and apply a restriction in the emission angle, which can simplify for example the posterior condenser optics.

Some present embodiments use Brightness Enhancement Films (BEF) atop the LED. These films are applied in other systems to backlights in order to increase their brightness (for example, by about 25% for one and about 50% for a crossed pair), but they typically employ highly reflective white coatings within the backlight. Some present embodiments, in contrast, use BEFs, in part, to enhance the LED luminance itself.

Additionally or alternatively, some present embodiments relate generally to luminance enhancement of light emitting diodes (LED), most particularly of top-emitting LEDs. This enhancement is via light recycling, whereby a portion of the light extracted from an LED is returned into it. This is effective when an LED can reflect a relatively high percentage of any external light illuminating it. Although LEDs are not engineered with this external reflectivity being a specific goal, attaining high LED efficiency generally increases that reflectivity.

Further, some embodiments provide luminance enhancement of LEDs over a restricted angular range with an etendue that is generally no larger than that of the LED chip itself. In some implementations these embodiments are evaluated based on how much they multiply chip-luminance and also by their output efficiency. In some applications, sufficiently high luminance-multiplication can outweigh low efficiency, as long as the increased heat load is dissipated effectively.

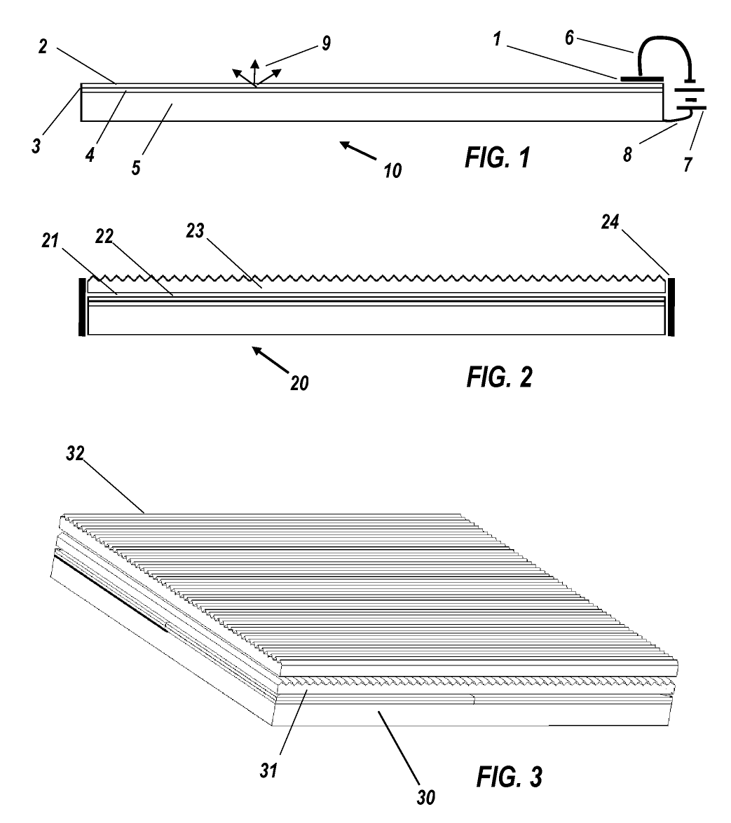

Thin-film LEDs differ significantly from previous LEDs in their nearly zero lateral emission. They are typically made by peeling the thin top-layer off a conventional, thick (e.g., 0.5 mm) chip, then bonding it to a lower metallic electrode, typically the anode. FIG. 1 shows a cross-section of thin-film LED 10, comprising upper anode 1, topmost semiconductor p-layer 2 (e.g., about 5 microns thick), emitting junction 3 (e.g., about 5 microns thick), and lower n-layer 4, bonded to bottom electrode 5, typically the cathode. Current source 7 provides power via upper feed-wire 6, in electrical contact with anode 1, and lower feed-wire 8, which is in electrical contact with cathode 5. With an aspect ratio over about 20:1, only a few percent of volume emission 9 of the active layer will escape out the sides, especially if the volume emission is not isotropic, but favored in the z direction (such as with quantum-well emitters). The category of thin-film LEDs encompasses thin configurations, generally regardless of the particularities of their fabrication. As such, substantially all emission is out the top.

In this regard there is a distinction in the application of surface roughening of LEDs to extract trapped light. Some high-efficiency LED designs have a bottom diffusely reflecting layer, such as silver, to extract trapped light. When the bottom layer is specularly reflecting, the top surface can be roughened instead (or in addition). Some roughening methods can simulate a refractive-index gradient and thereby suppress Fresnel reflections by the top surface and correspondingly better transmit trapped light to the outside. Ironically, these gradient-index reductions of internal Fresnel reflections enhance external reflectivity and thus assist the recycling utilized by the present embodiments.

Thicker LEDs, when placed inside a reflective cup but with a flat exit surface, are also top-emitting LEDs, and some present embodiments also apply to these LEDs.

FIG. 2 shows thin-film LED 20, identical to LED 10 of FIG. 1 but also comprising a linear prismatic retro-reflecting film 23 on top. This film will reflect around half of the light received from the chip back into it. This retroreflection will cause the angular emission into air to be restricted to about 50° full angle in this plane. An air gap 22 is incorporated into the LED 20 in some embodiments to aid in the BEF functioning of film 23, and in some instances allows the proper BEF functioning of film 23.

Further, in some embodiments the BEF pitch and thickness is small relative to the chip width, which at least in part aids in minimizing the light lost through the film's edges. This can be realized, for example, by using thin BEF's or by using large chips or even multiple chips with small spacing (preferably reflecting) in between. Additionally or alternatively, peripheral reflecting wall 24 can be used to surround both LED 20 and film 23. This reflector acts to prevent light spilling out the side edges of the prismatic film. This reflecting wall 24 can be dispensed with if the vertical or nearly vertical plane of the BEF film 23 is essentially smooth, because most of the light within the BEF will remain trapped by total internal reflection off the edge.

FIG. 3 is a perspective view showing thin-film LED 30 with first prismatic film 31 disposed just above the LED and with second prismatic film 32 above the first but oriented at 90° thereto. This embodiment emits a collimated output in an approximately circular cone of about 50° full angle.

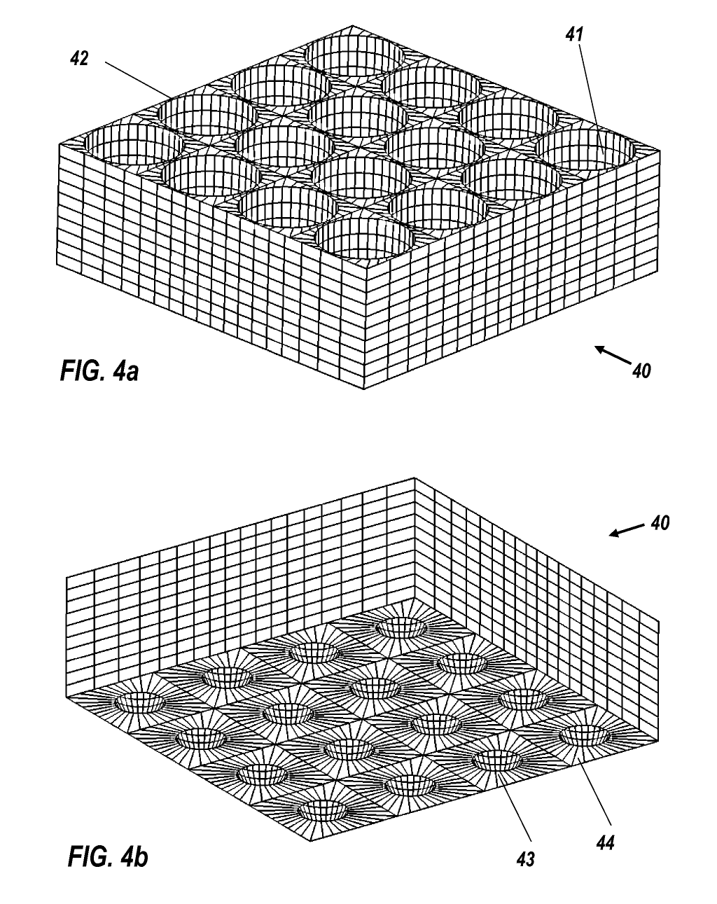

FIG. 4a is a perspective view of the top of a white block 40, pierced by compound parabolic concentrator (CPC) shaped holes 41, with exit apertures 42. The CPC holes can be more closely spaced in some embodiments in attempts at least in part to limit or avoid non-emitting zones, and in some instances spaced such that their apertures overlap, resulting in hexagonal or squared-off exit apertures. Also, the CPCs can be made by crossing two linear profiles, so the input and exit apertures will be, in general, rectangular. FIG. 4b is a further perspective view of block 40 of FIG. 4a, from below, also showing entry apertures 43 and bottom surface 44, which in some instances is diffusely reflecting (e.g., white).

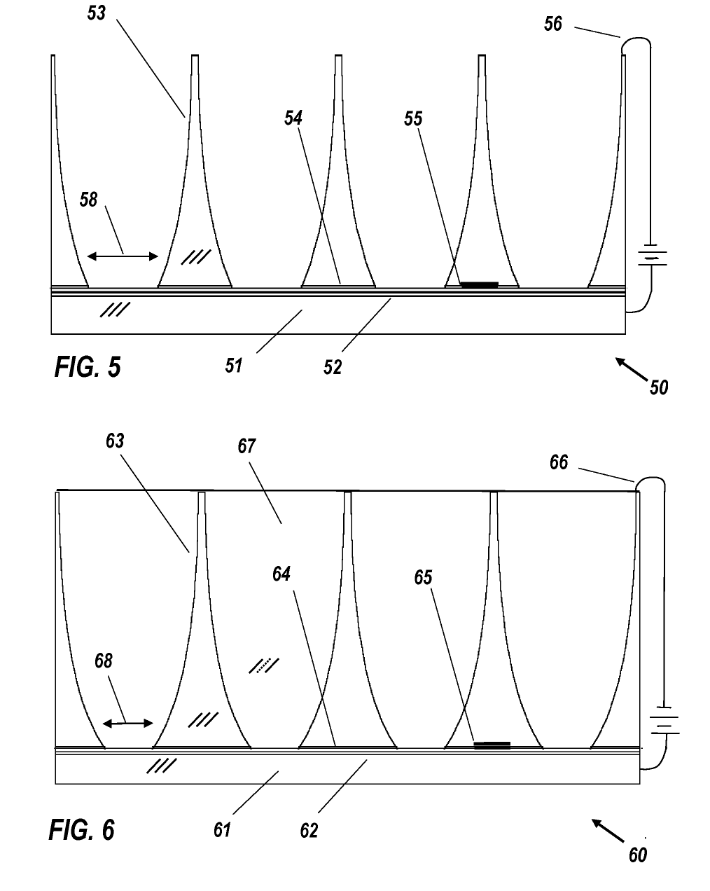

FIG. 5 shows LED 50 in cross-section, with unexaggerated vertical scale, comprising lower silver layer 51, and semiconductor chip 52 internally layered as in FIG. 1. Atop LED 50 is metal CPC-hole array 53, as in FIG. 4a. In some instances it is made with air gaps 54 to promote total internal reflection (TIR) for recycling within the chip. TIR is generally more efficient than the reflection off the metal that would result if there were no air gap. Also shown is cathode contact 55, incorporated into the metal of array 53 to deliver current to the top of LED 50, and thereby not blocking exiting light, which is often an inescapable aspect of conventional LEDs. DC source 56 delivers the requisite direct current for operating the device. Unlike typical thin-film LEDs, there is no transparent cover. Instead, LED 50 emits directly into air.

FIG. 6 depicts an LED 60 that is in correspondence with the LED 50 of FIG. 5, with the addition of transparent dielectric 67 filling the CPC array 63. In order to output approximately the same 30° emission as the open-CPC array 53 of FIG. 5, those array 63 of FIG. 6 are somewhat taller, and with smaller aperture width 68 than width 58 of FIG. 5. This gives the 50% greater concentration according to the refractive index (approximately 1.5) of dielectric 67. The CPC shapes of FIG. 6 have about a 20° output, which refracts to 30° as the light exits into air. Although the bottom-most part of transparent CPC 67 is too steep to operate by total internal reflection, an air gap between dielectric 67 and CPC array 63 will be beneficial over most of the CPC profile, which may introduce somewhat increased complexity.

Some of the potential of these embodiments for luminance enhancement depends upon their overall luminous output being reduced by less than the reduction in area of the apertures immediately over the LED, such as 58 of FIG. 5 or 68 of FIG. 6. The holes 42 of FIG. 4 have an area that is about 75% that of the LED the array covers. The 30° CPC profiles of FIG. 5 have about a 2:1 concentration in two dimensions, so that over the LED the hole fraction f_{H} is approximately 75%/4=19%, while the approximate 2.9:1 concentration of FIG. 6 gives about f_{H}=8.8%, little over half as much. In each case the total losses result in less flux reduction for there to be increased luminance.

Some embodiments have more and smaller CPCs than the 4×4 arrays of FIG. 5 and FIG. 6, so that trapped light, once it has been laterally diffused within the semiconductor, will not have as far to go to escape through the exit holes. This lateral light travel can be enhanced if a solid dielectric or reflective prism is placed between the LED and the CPCs. In some implementations, the CPC profiles, which may be difficult to make in small size, are approximated by a segmented linear profile and/or even by a straight profile.

The white coating corresponding to reference numeral 52 of FIG. 5 operates on the micro level through light-scattering by small transparent pieces of such high-index material, for example, as titanium dioxide (n˜2.5). The actual surface of such a white coating will exhibit about a portion of its 99% reflectivity, with deeper layers further scattering what is not scattered backwards to constitute reflection. A minimum thickness for total backscattering presumably is on the order of about tens to hundreds of microns (depending on the material being used), with a sacrifice of reflectivity for anything too thin, leaving some of the incident light allowed to be transmitted. Edmond Optics of New Jersey sells a highly reflective (diffuse) white coating called “Munsell White Reflective Coating”, which can be applied by a number of methods including spraying. The coating in its cured state is comprised primarily of a highly reflective Barium Sulfide binder. The coating yields a reflectance value of up to about 0.991 in the visible spectrum. The recommended minimum thickness of the coating to achieve the specified performance (above 98% reflectance in the visible spectrum) is about 0.64 mm, which is relatively large on the micro level scale.

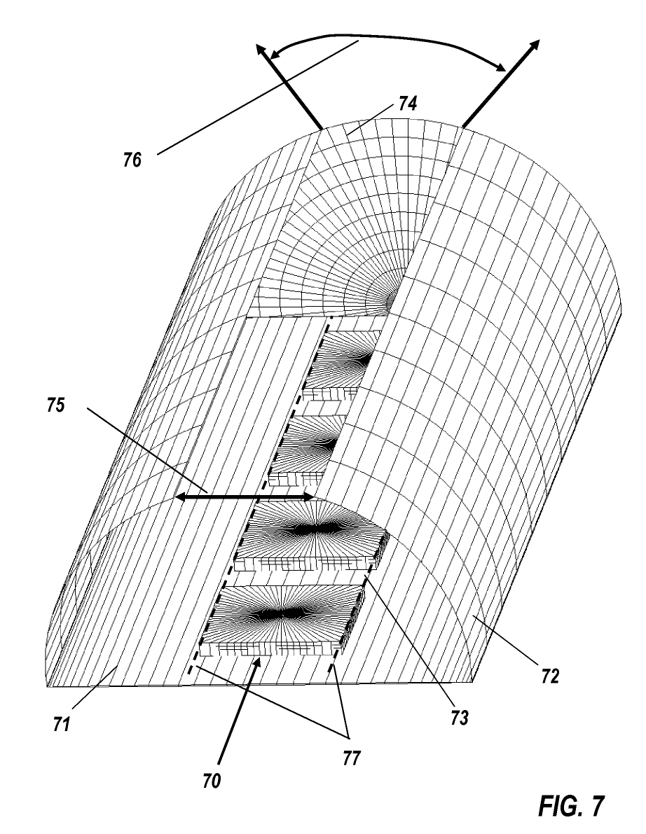

As a reflector profile, an ellipse will reflect a ray from a line between its foci to another point on the same line. FIG. 7 shows line array 70 of closely spaced thin-film LEDs, that are aligned and mounted on planar substrate 71. Slotted elliptical cylinder 72 has focal lines, depicted by dotted focal lines 77, and is reflective on its inside walls, thus returning substantially all light from the LEDs back to their surface, or to the spaces 73 between the LEDs (thus are generally highly reflective for better efficiency). Similarly, end wall 74 is specularly reflective in some implementations. The emission out slot 75 is transversely restricted to angle 76, although longitudinally it is as unrestricted as that of array 70 itself. Therefore, the device's etendue is reduced in the transversal plane as compared to that of the LEDs alone. This reduction may be useful, for example, for applications involving side injection into backlights, where the light collimation in this transversal plane is beneficial for efficient light extraction. Also with this application, multiple color chips can be used, with the recycling process providing some color mixing.

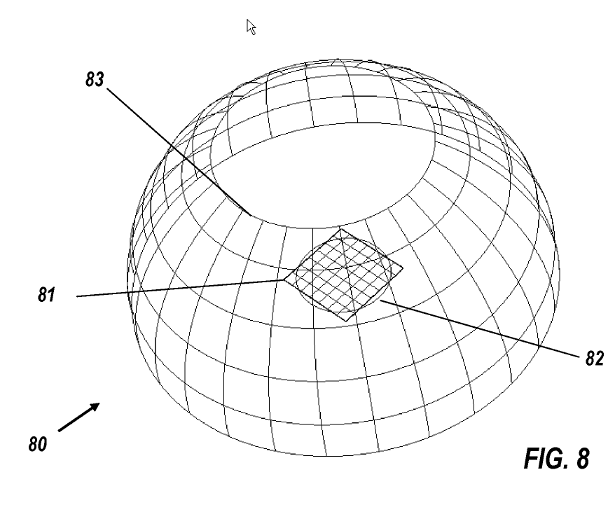

FIG. 8 shows the application of a rotationally symmetric elliptical cavity 80, according to some embodiments, with exit aperture 83, shaped at least in part to restrict the angular emission of an LED or LED cluster 81. The circle 82, described by the ellipse's foci, can be selected, in some implementations, to be approximately equal to the LED area.

When a rectangular LED or LED cluster is used, a non-rotational symmetric ellipsoid can be used, with its semi-axis in the plane of the LED, and showing a ratio similar to the aspect ratio of rectangular emitting area.

In embodiments based on FIG. 7 or FIG. 8, the elliptical profiles can be approximated by spherical ones for easier manufacturing. They can be either void or solid (with elliptical profile also along the exit aperture), the latter in some embodiments allowing the embodiment to act also as the primary optic dome encapsulating the LED.

Since the exit aperture of the ellipsoid will act as an aperture stop, a condenser lens can be placed on the exit aperture for more optimum control and definition of the emitted ray bundle. Said lens by itself or in combination with others, could image the luminance-enhanced LED onto the entry aperture of, for example, a kaleidoscope prism (so the circular aperture of the ellipsoid will define the circular numerical aperture of the kaleidoscope). Alternatively, it could image the LED to infinity to illuminate a set of Kohler-integrating fly-eye lenses. In some other embodiments, the exit aperture is set as a rectangle with an aspect ratio, for example, of 4:3 or 16:9, typical for video and HD. Then the lens at the exit of the ellipsoid is the first element of a Kohler integrating system, while a second lens images the rectangular exit of the ellipsoid onto the spatial light modulator.

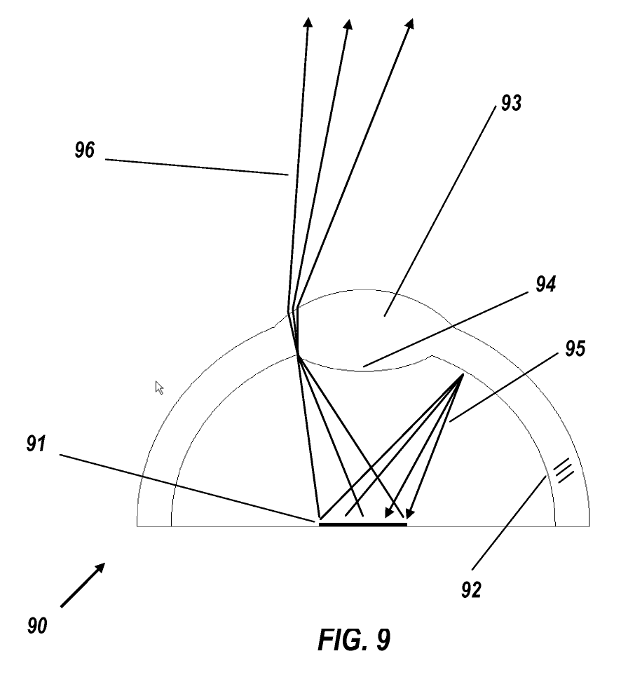

FIG. 9 shows the cross section of an air-filled rotational symmetric elliptical reflector 90, operable for increasing the luminance of LED or LED cluster 91. While the device is made, according to some implementations, in one piece of transparent dielectric, it has interior specular reflective coating 92 surrounding central condenser lens 93. Coating 92 is shown reflecting rays 95 back to the LED or LED cluster 91. Condenser lens 93 refracts rays 95 from the LED or LED cluster 91.

For the embodiments of FIG. 8 and FIG. 9 the LED cluster can be comprised of LEDs of a variety of colors. In these embodiments the specular reflectivity of the interior walls provides color mixing, although in principle they typically cannot provide complete mixing because the color of each LED's own emission is unchanged in direction once it is emitted. Thus, for example, a mildly scattering (10°) holographic diffuser can be molded onto surface 94 of FIG. 9, to assist in color mixing.

Some embodiments provide luminance enhancement. In some implementations, light is reflected by the one or more LEDs. The amount of light reflected by LEDs can be used as a method of light-recycling to increase LED luminance. Some embodiments are implemented with a single standard Brightness Enhancement Film or two-crossed BEFs. Additionally or alternatively, an array of CPCs positioned over the LED is utilized. Further, some embodiments use linear or rotational elliptical cavity with enhanced luminance and narrowed output angle.

While the invention herein disclosed has been described by means of specific embodiments and applications thereof, numerous modifications and variations could be made thereto by those skilled in the art without departing from the scope of the invention set forth in the claims.

What is claimed is:

1. A luminance-enhanced light source, comprising a thin-film LED mounted on a substrate and with a defined upper surface approximately hemispherically emitting light, said upper surface being diffusely transmissive, a lower first layer of identically defined linear prismatic film separated from said upper surface by a non-evanescent air gap so as to cover said upper surface, a upper second layer of linear prismatic film, identical to but oriented orthogonally to said first layer, and a circumferential vertical reflective wall bordering on both of said first and second layers and extending in height from said substrate to a top of said second layer.

2. A luminance-enhanced light source comprising a thin-film LED with a defined upper surface hemispherically emitting light, a reflective upper layer in optical contact with said LED, said upper layer having an array of holes providing passage of luminance-enhanced light out of said LED, and an array of collimating means aligned in correspondence to said holes in order to receive said luminance-enhanced light and to expand a cross sectional exit area of the luminance-enhanced light to a majority of an area of said upper surface of said LED.

3. The light source of claim 2 wherein said array of collimating means also comprises an upper electrode of said LED.

4. The system of claim 2 wherein said array of collimating means comprises a multiplicity of compound parabolic concentrators.

5. A luminance-enhanced light source comprising a line of a plurality of spaced LEDs and two linearly swept elliptical reflectors disposed symmetrically on opposing sides of the line of LEDs and defining an aperture above said line of LEDs, said reflectors with elliptical profiles each having a first focus on an opposite edge of said line of LEDs and a second focus on an opposite edge of said aperture.

6. The system of claim 5 further comprising specularly reflective portions of the ellipsoid covering said aperture.

7. A luminance-enhanced light source comprising an LED and a rotationally symmetric elliptical reflector, said reflector with elliptical profile having a circular focus defined at an opposite edge of the circular profile from the elliptical reflector where the circular focus has a radius substantially encompassing said LED.

8. The system of claim 7 further comprising a condenser lens positioned at an exit aperture of said elliptical reflector.

9. The system of claim 7 further comprising an LED cluster comprising the LED, where the radius of the circular focus substantially encompasses the LED cluster.
